(19) United States
(12) Patent Application Publication
(10) Pub. No.: US 2005/0136583 A1
(43) Pub. Date: Jun. 23, 2005

(54) Advanced strained-channel technique to improve CMOS performance

(75) Inventors: Chien-Hao Chen, Jhuangwei Township (TW); Chia-Lin Chen, Hsinchu (TW); Tze-Liang Lee, Hsinchu (TW); Shih-Chang Chen, Hsin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Co.

(21) Appl. No.: 10/744,746

(22) Filed: Dec. 23, 2003

(51) Int. Cl. H01L 21/8238; H01L 21/3205; H01L 21/4763

(52) U.S. Cl. 438/199; 438/585

(57) ABSTRACT

A method of improving CMOS device performance, comprising the following steps. A structure having a gate electrode formed thereover and a channel formed thereunder is provided. The gate electrode having an initial lower width and an initial upper width. A capping layer having a tensile stress is formed over the structure and the gate electrode. The gate electrode is annealed to achieve tensile stress in the channel.

### BACKGROUND OF THE INVENTION

Mechanical stress control in the channels of CMOS devices significantly impacts the devices' performance.

The “Mechanical Stress Effect of Etch-Stop Nitride and its Impact on Deep Submicron Transistor Design,” Shinya Ito et. al., IEEE, © 2000, pages 00-247 to 00-250 article, focusing upon the effect of a plasma-enhanced chemical vapor deposition (PECVD) nitride contact-etch-stop layer, reports that process-induced mechanical stress affects the performance of short-channel CMOSFET's.

The “Local Mechanical-Stress Control (LMC): A New Technique for CMOS-Performance Enhancement,” A. Shimuzu et. al., IEEE© 2001, pages 19.4.1 to 19.4.4 describes a technique dubbed by the authors “local mechanical-stress control” (LMC) to enhance the CMOS current drivability.

The “A Highly Dense, High-Performance 130 nm node CMOS Technology for Large Scale System-on-a-Chip Applications,” F. Ootsuka et. Al., IEEE© 2000, pages 23.5.1 to 23.5.4 describes a 130 nm node CMOS technology with a self-aligned contact system.

The “NMOS Drive Current Reduction Caused by Transistor Layout and Trench Isolation Induced Stress,” Gregory Scott et. al., IEEE© 1999, pages 34.4.1 to 34.4.4 describes a sensitivity to layout of NMOS transistors of identical gate length.

U.S. Pat. No. 6,555,839B2 to Fitzgerald describes a buried channel stained silicon FET using a supply layer created through ion implantation.

U.S. Pat. No. 6,492,216 B1 to Yeo et al. describes a method of forming a transistor with a strained channel.

U.S. Pat. No. 5,668,387 to Streit et al. describes a relaxed channel high electron mobility transistor.

U.S. Patent Application Publication No. 2002/0011603 A1 to Yagishita et al. describes a semiconductor device in which an NMOSFET and a PMOSFET are formed in a silicon substrate and method of manufacturing the same.

### SUMMARY OF THE INVENTION

Accordingly, it is an object of one or more embodiments of the present invention to provide a method of fabricating a CMOS device having improved performance.

Other objects will appear hereinafter.

It has now been discovered that the above and other objects of the present invention may be accomplished in the following manner. Specifically, a structure having a gate electrode formed thereover and a channel formed thereunder is provided. The gate electrode having an initial lower width and an initial upper width. A capping layer having a tensile stress is formed over the structure and the gate electrode. The gate electrode is annealed to achieve tensile stress in the channel.

### BRIEF DESCRIPTION OF THE DRAWINGS

The present invention will be more clearly understood from the following description taken in conjunction with the accompanying drawings in which like reference numerals designate similar or corresponding elements, regions and portions and in which:

FIGS. 1 to 7 schematically illustrate cross-sectional views of the preferred embodiment of the present invention with FIGS. 5 and 6 illustrating a larger portion of the wafer for ease of understanding.

### DETAILED DESCRIPTION OF THE PREFERRED EMBODIMENT

Information Known to the Inventors—not to be Considered Prior Art

The following is information known to the inventors and is not to be considered prior art for the purposes of this invention.

Some local mechanical stress control technologies have been reported to improve device performance by utilizing a contact etch-stop silicon nitride (Si₃N₄) layer after silicide formation as a stressor. However, the NMOS and PMOS drive current are therefore in a tradeoff relationship in terms of this uniaxial mechanical stress.

Recently, it has further been reported that using a tensile CVD silicon oxide (SiO₂) capping layer before the source/drain (S/D) annealing can cause a tensile strained channel in NMOS to improve drivability without degradation of PMOS. However, high tensile stress is difficult to obtain in SiO₂ film and only about 1E9 dyne/cm² stress is achieved.

Present Invention

In this invention, we propose an advanced yet simple method to obtain a highly tensile, local-strained channel device by using a low-temperature Si₃N₄ film, or an SiO₂/Si₃N₄ stack, with high tensile stress and a high HF etch rate. Combining with the implantation and annealing, a highly tensile stress-channel can be achieved.

In addition, this capping film can directly serve as a resistant protection layer for subsequent CMOS processes, utilizing the high HF etch rate properties to selectively remove the Si₃N₄ film to form silicide.

The inventors have discovered that the removal of the extra additives adsorbed on the surface to be polished, and hence the increased chemical bonding between the abrasives, e.g. CeO₂, and the surface, e.g. silicon oxide, before the completion of the polishing is key to reducing the scratching of the surface and improving the yield.

Initial Structure—FIG. 1

As shown in FIG. 1, structure 10 includes a polysilicon (poly) gate electrode 14 formed thereover with an intervening gate oxide layer 12 formed thereupon.

A compressive channel 11 is below the gate oxide layer 12 within the structure 10.

Poly gate 14 has: a bottom and top width of preferably from about 100 to 10,000 Å and more preferably from about 30 to 80 Å; and a height of preferably from about 100 to 10,000 Å and more preferably from about 500 to 2000 Å.

Low doped drains (LDD) 18 are formed in structure 10 outboard of poly gate electrode 14/gate oxide layer 12 to a depth of preferably from about 100 to 1000 Å and more preferably from about 200 to 400 Å at a concentration of preferably from about 1E19 to 1E22 atoms/cm² and more preferably from about 1E20 to 1E21 atoms/cm² using As, P, In, Ge, B, Sb, C, BF₂ or O atoms and more preferably As atoms.

Sidewall spacers 16 are formed over the exposed sidewalls 15 of gate electrode 14/gate oxide layer 12 to a maximum width of preferably from about 100 to 2000 Å and more preferably from about 300 to 1000 Å.

Structure 10 is preferably a silicon or germanium substrate and is more preferably a silicon substrate. Gate oxide layer 12 is preferably comprised of silicon oxide (SiO₂), SiON, Si₃N₄ or high-k dielectric (i.e. a dielectric constant (k) of greater than about 3.0) and is more preferable silicon oxide (oxide). Sidewall spacers 16 are preferably comprised of Si₃N₄, SiO₂ or TEOS and are more preferably Si₃N₄.

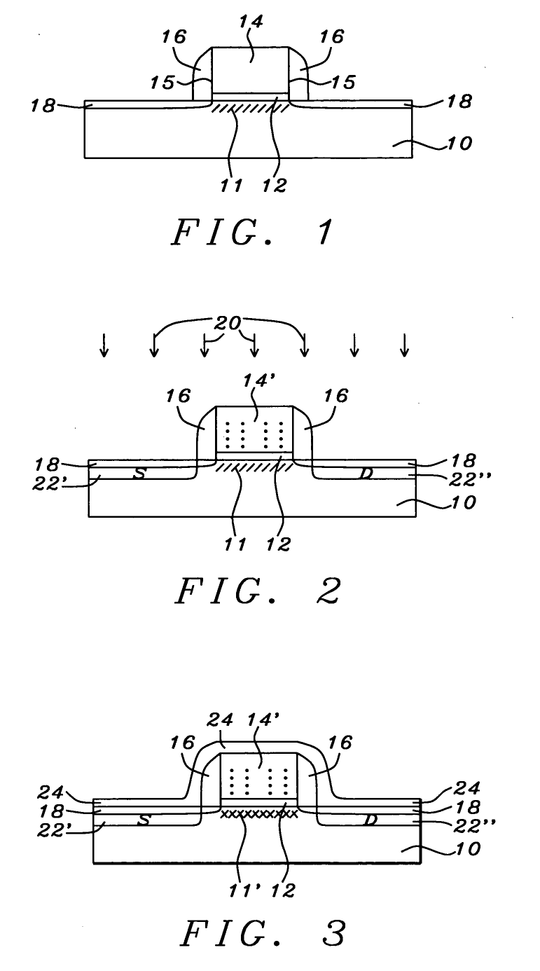

Gate Electrode 14 and Source/Drain Implant 20—FIG. 2

As shown in FIG. 2, a gate electrode 14 and source/drain (S/D) implant 20 is performed to: convert poly gate 14 to amorphous poly gate 14′; and form source implant (source) 22′ and drain implant (drain) 22″, for example, respectively, outboard of sidewall spacers 16.

S/D implants 22′, 22″ are formed to a depth of preferably from about 100 to 5000 Å and more preferably from about 500 to 1000 Å at a concentration of preferably from about 1E19 to 1E22 atoms/cm² and more preferably from about 1E20 to 1E21 atoms/cm² preferably using As, P, In, Ge, B, Sb, C, BF₂ or O atoms and more preferably As atoms.

Formation of Gate Activation Capping Layer 24—FIG. 3

As shown in FIG. 3, a gate activation capping layer (capping layer) 24 is then formed over structure 10, gate electrode 14′ and sidewall spacers 16. This converts compressive channel 11 to tensile channel 11′. Capping layer 24 is preferably comprised of silicon nitride (Si₃N₄), a silicon oxide/silicon nitride stack or SiNC, is more preferably silicon nitride or a silicon oxide/silicon nitride stack and is most preferably a silicon oxide/silicon nitride stack.

A) If a silicon nitride (Si₃N₄) capping layer 24 is formed, it is formed under the following conditions to form a low temperature nitride capping layer having high tensile stress and a high HF etch rate:
temperature: preferably from about 350 to 600° C. and more preferably from about 450 to 550° C.;
thickness: preferably from about 100 to 1000 Å and more preferably from about 200 to 500 Å;
tensile stress: preferably from about 1.0E9 to 2.0E10 dyne/cm², more preferably from about 5.0E9 to 1.5E10 dyne/cm² and most preferably about 1.0E10 dyne/cm²; (it is noted that if a SiO₂/SiN capping layer 24 is formed, that will result in a lower stress level because the SiO2 will slightly relax the stress from SiN);
HF etching rate: preferably from about 400 to 10 Å/minute @ 1% HF and more preferably from about 100 to 200 Å/minute @ 1% HF (etching rate is tunable, i.e. the etching rate of the SiN film can be tuned by changing the deposition temperature, gas ratio and pressure);
precursor: preferably DCS (Si₂Cl₆), HCD (Si₂Cl₆), BTBAS (C₈H₂₂N₂Si); and
tool: preferably LPCVD, ALD, RTCVD, single wafer system or batch type method.

B) If a silicon oxide/silicon nitride stack capping layer 24 is formed, the silicon oxide layer portion is formed under the following conditions (with the silicon nitride layer portion being formed under the conditions noted above for the silicon nitride capping layer 24):
temperature: preferably from about 400 to 600° C. and more preferably from about 500 to 600° C.;
thickness: preferably from about 10 to 100 Å and more preferably from about 50 to 100 Å;
HF etching rate: preferably from about 400 to 100 Å/minute @ 1% HF and more preferably from about 300 to 200 Å/minute @ 1% HF;
precursor: preferably HCD (SiCl₆), TEOS, BTBAS (C₈H₂₂N₂Si) and more preferably BTBAS; and
tool: preferably LPCVD, ALD, RTCVD, single wafer system or batch type method.

The nitride layer portion of the silicon oxide/silicon nitride stack capping layer 24 has a thickness of preferably from about 100 to 1000 Å and more preferably from about 200 to 500 Å.

Whether the capping layer 24 is comprised of silicon nitride or a silicon oxide/silicon nitride stack, the 300 to 600° C. deposition temperature of the silicon nitride layer/layer portion has no impact upon the ultrashallow junction profile. It is noted that the silicon oxide layer portion of the silicon oxide/silicon nitride stack is deposited from about 500 to 600° C. which also does not impact upon the ultrashallow junction profile. This temperature range is much lower that the phase transition temperature of the amorphous silicon gate electrode 14′ with little impact upon the S/D dopant profile and is thus good for ultra shallow junction (USJ) formation which is promising for sub-90 nm CMOS. Also, high tensile stress can be easily achieved for the LPCVD HCD-SiN, ALD DCS-SiN, LPCVD DS-SIN (where DS is Si₂H₆) and the LPCVD BTBAS-SiN layer 24/layer portion of capping layer 24. The from about 1 to 2 Gpa high tensile stress film can largely enhance the channel strain (see below) and this tensile stress is tunable by temperature or the gas ratio for specific applications.

There is excellent thickness uniformity control, i.e. about 1%, in forming the capping layer 24. There is also excellent step coverage and pattern loading effect for the capping layer 24. Gate Electrode 14′ and S/D 22′, 22″ Activation—FIG. 4

As shown in FIG. 4, an anneal 27 is performed on the structure shown in FIG. 3. The anneal 27 is performed at a furnace temperature of preferably from about 800 to 1100° C. and more preferably from about 900 to 1000° C. preferably using a rapid thermal anneal (RTA) or a spike anneal and more preferably a spike anneal.

The amorphous poly gate electrode 14′ re-crystallizes so that a poly gate electrode 14′ expansion occurs at its top end as shown in FIG. 4 causing residual compressive stress (the vertical dotted lines in FIG. 4 illustrate the re-crystallization).

The tensile stress of (SiN) capping layer 24 enhances the compressive stress in the expanded poly gate electrode 14″ to achieve high tensile stress in the tensile channel 11′ which improves the device performance.

Photoresist Layer 30—FIG. 5

As shown in FIG. 5, a patterned photoresist layer 30 is formed over the structure of FIG. 4. The patterned photoresist layer 30 masks the portion(s) of capping layer 24 that will remain (see below).

The tensile SiN capping layer 21 serves as a resist protect layer to replace conventional RPO (resist protect oxide) and protects some portion of the substrate from forming silicide at the subsequent silicide step (see below).

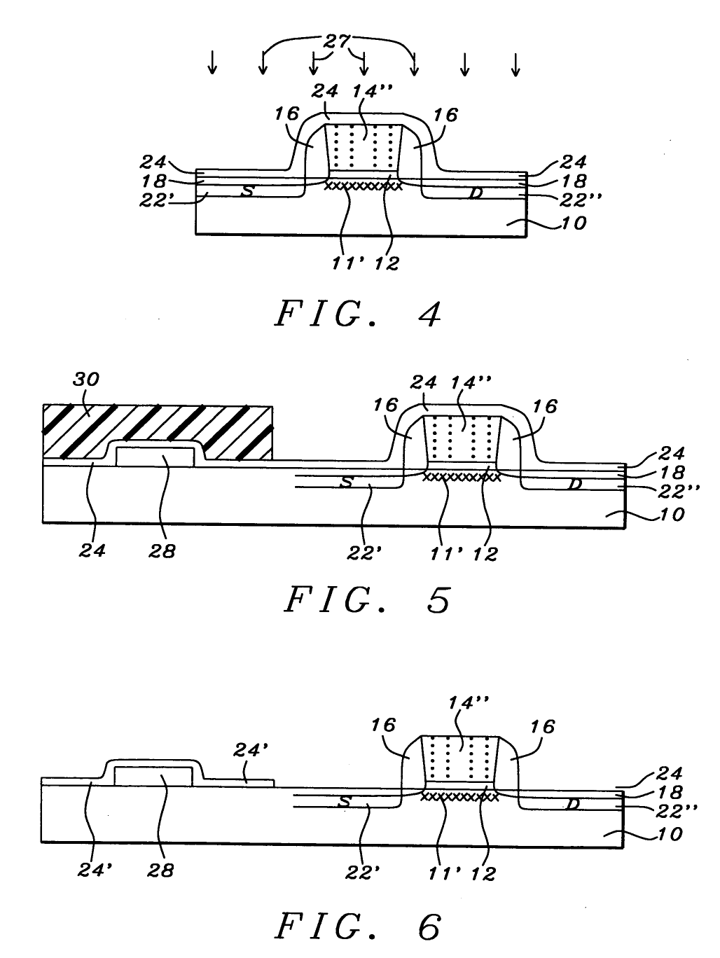

Removal of Exposed Capping Layer 24—FIG. 6

As shown in FIG. 6, the portion(s) of exposed capping layer 24 not masked by patterned photoresist layer 30 is/are removed, preferably by: (1) the direct use of an HF wet etch/dip, by using H₃PO₄ or by a dry etch and more preferably by H₃PO₄ when capping layer 24 is comprised of SiN; and (2) by dry etching when capping layer 24 is comprised of SiO₂/SiN.

It is noted that the low temperature capping layer 24, whether it be low temperature SiN or low temperature SiO₂/SiN stack, exhibit a significantly higher HF etch rate than thermal oxide and so capping layer 24 may be easily removed by a direct HF dip which also reduces (thermal silicon oxide) shallow trench isolation (STI) loss (compared to oxide capping layer portion of oxide/nitride stack capping layer 24). For example the HF etch rate of LT HCD-SiN (i.e. low temperature SiN film formed by HCD precursor) is from about 300 to 500 Å/minute @ 450° C. while the HF etch rate of thermal oxide is about 35 Å/minute @ 450° C.

If capping layer 24 is comprised entirely of SiN, then the SiN capping layer 24 may also be removed using H₃PO₄ or dry etching which also reduces STI loss.

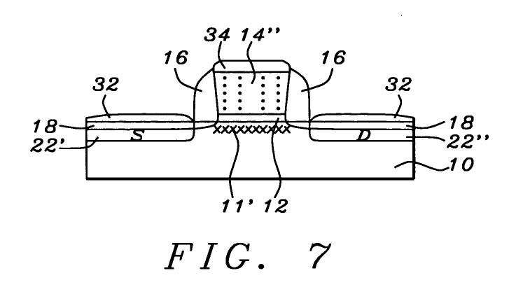

Formation of Silicide Portions 32, 34—FIG. 7

As shown in FIG. 7, silicide portions 32 are formed over source/drain 22′, 22″ and silicide portion 34 is formed over poly gate electrode 14″. Silicide portions 32, 34 are preferably Co-silicide or Ni-silicide and are more preferably Co-silicide. That is silicide portions 32, 34 are formed over those regions without patterned capping layer 24′ protection and serve as resist protect layer.

Subsequent processing may then proceed for standard CMOS back-end processing.

### ADVANTAGES OF THE PRESENT INVENTION

The advantages of one or more embodiments of the present invention include:
1. tensile strained channel can be largely enhanced by high tensile capping layer formed in accordance with the present invention;
2. NMOS performance can be much improved without degradation in PMOS performance;
3. the stress and etching rate of the capping layer formed in accordance with the present invention can be tuned to meet specific applications;
4. the low temperature deposition of the capping layer formed in accordance with the present invention has no impact on USJ formation;
5. the capping layer formed in accordance with the present invention may serve as a resist protect layer without additional oxide RPO formation and reduces STI loss;
6. the low temperature formed capping layer formed in accordance with the present invention exhibits good thickness uniformity, step coverage and pattern loading effect; and
7. the method of the present invention is a simple and effect method and can be directly integrated into current CMOS processes.

While particular embodiments of the present invention have been illustrated and described, it is not intended to limit the invention, except as defined by the following claims.

1. A method of improving CMOS device performance, comprising the steps of:
providing a structure 10 having a gate electrode formed thereover and a channel formed thereunder; the gate electrode having an initial lower width and an initial upper width;
forming a capping layer over the structure and the gate electrode; the capping layer having a tensile stress; and
annealing the gate electrode to achieve tensile stress in the channel.

2. The method of claim 1, wherein the capping layer is formed at a temperature of about 600° C. or less.

3. The method of claim 1, wherein the annealing of the gate electrode re-crystallizes and expands the gate electrode producing compressive stress.

4. The method of claim 1, wherein the annealing of the gate electrode re-crystallizes and expands the gate electrode producing compressive stress; and wherein the tensile stress of the capping layer enhances the compressive stress of the re-crystallized gate electrode.

5. The method of claim 1, wherein the recrystallized gate electrode having a final upper width greater than the initial upper width.

6. The method of claim 1, wherein the structure is a silicon substrate or a germanium substrate.

7. The method of claim 1, wherein the structure is a silicon substrate.

8. The method of claim 1, wherein the gate electrode is amorphous polysilicon.

9. The method of claim 1, wherein the capping layer is comprised of:
silicon nitride; or
a silicon oxide/silicon nitride stack.

10. The method of claim 1, wherein the capping layer is comprised of:
silicon nitride formed at a temperature of from about 350 to 600° C.; or
a silicon oxide/silicon nitride stack formed at a temperature of about 600° C. or less.

11. The method of claim 1, wherein the capping layer has a tensile stress of from about 1.0E9 to 2.0E10 dyne/cm².

12. The method of claim 1, wherein the capping layer has a tensile stress of from about 5.0E9 to 1.5E10 dyne/cm².

13. The method of claim 1, wherein the capping layer has a tensile stress of about 1.0E10 dyne/cm².

14. The method of claim 1, wherein the capping layer has an HF etch rate of about 400 to 10 Å/minute @ 1% HF.

15. The method of claim 1, wherein the capping layer has an HF etch rate of about 100 to 200 Å/minute @ 1% HF.

16. The method of claim 1, wherein the gate electrode is polysilicon and, before the step of forming the capping layer, including the step of conducting an implant into the gate electrode and the adjacent substrate to:
convert the polysilicon gate electrode to amorphous polysilicon; and
form source and drain implants within the structure 10 adjacent and outboard of the amorphous polysilicon gate electrode.

17. The method of claim 1, wherein the gate electrode is polysilicon and, before the step of forming the capping layer, including the step of conducting an implant into the gate electrode and the adjacent substrate to:
convert the polysilicon gate electrode to amorphous polysilicon; and
form source and drain implants within the structure adjacent and outboard of the amorphous polysilicon gate electrode;
and including the subsequent steps of:
removing the capping layer from at least over the re-crystallized gate electrode and portions of the source and drain implants; and
forming silicide portions over the exposed source and drain implants and the exposed re-crystallized gate electrode.

18. The method of claim 1, wherein the gate electrode is polysilicon and, before the step of forming the capping layer, including the step of conducting an implant into the gate electrode and the adjacent substrate to:
convert the polysilicon gate electrode to amorphous polysilicon; and
form source and drain implants within the structure adjacent and outboard of the amorphous polysilicon gate electrode;
and including the subsequent steps of:
removing the capping layer from at least over the re-crystallized gate electrode and portions of the source and drain implants; and
forming silicide portions over the exposed source and drain implants and the exposed re-crystallized gate electrode;
wherein the capping layer is removed using:
HF;
H₃PO₄ or
a dry etch.

19. The method of claim 1, wherein the gate electrode is annealed at a temperature of from about 800 to 1100° C.

20. The method of claim 1, wherein the gate electrode is annealed at a temperature of from about 900 to 1000° C.

21. The method of claim 1, wherein the gate electrode is annealed using a furnace anneal, a rapid thermal anneal or a spike anneal.

22. A method of improving CMOS device performance, comprising the steps of:
providing a structure 10 having a gate electrode formed thereover and a channel formed thereunder; the gate electrode having an initial lower width and an initial upper width;
forming a capping layer over the structure and the gate electrode; the capping layer being formed at a temperature of about 600° C. or less; the capping layer having a tensile stress; and
annealing the gate electrode to re-crystallize and expand the gate electrode producing compressive stress; the tensile stress of the overlying capping layer enhancing the compressive stress of the re-crystallized gate electrode to achieve tensile stress in the channel.

23. The method of claim 22, wherein the re-crystallized gate electrode having a final upper width greater than the initial upper width.

24. The method of claim 22, wherein the structure is a silicon substrate or a germanium substrate.

25. The method of claim 22, wherein the structure is a silicon substrate.

26. The method of claim 22, wherein the gate electrode is amorphous polysilicon.

27. The method of claim 22, wherein the capping layer is comprised of:
silicon nitride; or
a silicon oxide/silicon nitride stack.

28. The method of claim 22, wherein the capping layer is comprised of:
silicon nitride formed at a temperature of from about 350 to 600° C.; or
a silicon oxide/silicon nitride stack formed at a temperature of about 600° C. or less.

29. The method of claim 22, wherein the capping layer has a tensile stress of from about 1.0E9 to 2.0E10 dyne/cm².

30. The method of claim 22, wherein the capping layer has a tensile stress of from about 5.0E9 to 1.5E10 dyne/cm².

31. The method of claim 22, wherein the capping layer has a tensile stress of about 1.0E10 dyne/cm².

32. The method of claim 22, wherein the capping layer has an HF etch rate of about 400 to 10 Å/minute @ 1% HF.

33. The method of claim 22, wherein the capping layer has an HF etch rate of about 100 to 200 Å/minute @ 1% HF.

34. The method of claim 22, wherein the gate electrode is polysilicon and, before the step of forming the capping layer, including the step of conducting an implant into the gate electrode and the adjacent substrate to:
convert the polysilicon gate electrode to amorphous polysilicon; and
form source and drain implants within the structure adjacent and outboard of the amorphous polysilicon gate electrode.

35. The method of claim 22, wherein the gate electrode is polysilicon and, before the step of forming the capping layer, including the step of conducting an implant into the gate electrode and the adjacent substrate to:
convert the polysilicon gate electrode to amorphous polysilicon; and
form source and drain implants within the structure adjacent and outboard of the amorphous polysilicon gate electrode;
and including the subsequent steps of:
removing the capping layer from at least over the re-crystallized gate electrode and portions of the source and drain implants; and
forming silicide portions over the exposed source and drain implants and the exposed re-crystallized gate electrode.

36. The method of claim 22, wherein the gate electrode is polysilicon and, before the step of forming the capping layer, including the step of conducting an implant into the gate electrode and the adjacent substrate to:
convert the polysilicon gate electrode to amorphous polysilicon; and
form source and drain implants within the structure adjacent and outboard of the amorphous polysilicon gate electrode;
and including the subsequent steps of:
removing the capping layer from at least over the re-crystallized gate electrode and portions of the source and drain implants; and
forming silicide portions over the exposed source and drain implants and the exposed re-crystallized gate electrode;
wherein the capping layer is removed using:
HF;
H₃PO₄ or
a dry etch.

37. The method of claim 22, wherein the gate electrode is annealed at a temperature of from about 800 to 1100° C.

38. The method of claim 22, wherein the gate electrode is annealed at a temperature of from about 900 to 1000° C.

39. The method of claim 22, wherein the gate electrode is annealed using a furnace anneal, a rapid thermal anneal or a spike anneal.

40. A method of improving CMOS device performance, comprising the steps of:
providing a structure 10 having a gate electrode formed thereover and a channel formed thereunder; the gate electrode having an initial lower width and an initial upper width;
forming a capping layer over the structure and the gate electrode; the capping layer being formed at a temperature of about 600° C. or less; the capping layer having a tensile stress of from about 1.0E9 to 2.0E10 dyne/cm²; and
annealing the gate electrode to re-crystallize and expand the gate electrode producing compressive stress; the tensile stress of the overlying capping layer enhancing the compressive stress of the re-crystallized gate electrode to achieve tensile stress in the channel.

41. The method of claim 40, wherein the re-crystallized gate electrode having a final upper width greater than the initial upper width.

42. The method of claim 40, wherein the structure is a silicon substrate or a germanium substrate.

43. The method of claim 40, wherein the structure is a silicon substrate.

44. The method of claim 40, wherein the gate electrode is amorphous polysilicon.

45. The method of claim 40, wherein the capping layer is comprised of:
silicon nitride; or
a silicon oxide/silicon nitride stack.

46. The method of claim 40, wherein the capping layer is comprised of:
silicon nitride formed at a temperature of from about 350 to 600° C.; or
a silicon oxide/silicon nitride stack formed at a temperature of about 600° C. or less.

47. The method of claim 40, wherein the capping layer has a tensile stress of from about 5.0E9 to 1.5E10 dyne/cm².

48. The method of claim 40, wherein the capping layer has a tensile stress of about 1.0E10 dyne/cm².

49. The method of claim 40, wherein the capping layer has an HF etch rate of about 400 to 10 Å/minute @ 1% HF.

50. The method of claim 40, wherein the capping layer has an HF etch rate of about 100 to 200 Å/minute @ 1% HF.

51. The method of claim 40, wherein the gate electrode is polysilicon and, before the step of forming the capping layer, including the step of conducting an implant into the gate electrode and the adjacent substrate to:
convert the polysilicon gate electrode to amorphous polysilicon; and
form source and drain implants within the structure adjacent and outboard of the amorphous polysilicon gate electrode.

52. The method of claim 40, wherein the gate electrode is polysilicon and, before the step of forming the capping layer, including the step of conducting an implant into the gate electrode and the adjacent substrate to:
convert the polysilicon gate electrode to amorphous polysilicon; and
form source and drain implants within the structure adjacent and outboard of the amorphous polysilicon gate electrode;
and including the subsequent steps of:
removing the capping layer from at least over the re-crystallized gate electrode and portions of the source and drain implants; and
forming silicide portions over the exposed source and drain implants and the exposed re-crystallized gate electrode.

53. The method of claim 40, wherein the gate electrode is polysilicon and, before the step of forming the capping layer, including the step of conducting an implant into the gate electrode and the adjacent substrate to:
convert the polysilicon gate electrode to amorphous polysilicon; and
form source and drain implants within the structure adjacent and outboard of the amorphous polysilicon gate electrode;
and including the subsequent steps of:
removing the capping layer from at least over the re-crystallized gate electrode and portions of the source and drain implants; and
forming silicide portions over the exposed source and drain implants and the exposed re-crystallized gate electrode;
wherein the capping layer is removed using:
HF;
H₃PO₄ or
a dry etch.

54. The method of claim 40, wherein the gate electrode is annealed at a temperature of from about 800 to 1100° C.

55. The method of claim 40, wherein the gate electrode is annealed at a temperature of from about 900 to 1000° C.

56. The method of claim 40, wherein the gate electrode is annealed using a furnace anneal, a rapid thermal anneal or a spike anneal.
